(19) United States
(12) Patent Application Publication
(10) Pub. No.: US 2024/0055450 A1
(43) Pub. Date: Feb. 15, 2024

(54) SEMICONDUCTOR DEVICE

(71) Applicant: SONY SEMICONDUCTOR SOLUTIONS CORPORATION, Kanagawa (JP)

(72) Inventor: Tetsuya SUGIMOTO, Kumamoto (JP)

(73) Assignee: SONY SEMICONDUCTOR SOLUTIONS CORPORATION, Kanagawa (JP)

(21) Appl. No.: 18/264,947

(22) PCT Filed: Feb. 9, 2022
(86) PCT No.: PCT/JP2022/005065

§ 371 Date: Aug. 10, 2023

(30) Foreign Application Priority Data
Feb. 17, 2021 (JP) 2021-023553

(51) Int. Cl. H01L 27/146

(52) U.S. Cl. CPC H01L 27/14618; H01L 27/14683

(57) ABSTRACT

The present disclosure provides a semiconductor device capable of suppressing peeling of sealing resin, and an electric device. A semiconductor device according to a first aspect of the present disclosure includes: a substrate; a frame having a wall portion that is annularly arranged on the substrate and has a plurality of projection portions on an upper surface, the frame having a groove portion provided on the upper surface of the wall portion in correspondence to each of the projection portions; a semiconductor chip arranged in a region surrounded by the wall portion on the substrate; and a lid portion arranged on the upper surface of the wall portion and sealing the semiconductor chip.

### TECHNICAL FIELD

An embodiment of the present disclosure relates to a semiconductor device.

### BACKGROUND ART

Conventionally, a semiconductor device is enclosed in a package to prevent moisture and the like. Among such semiconductor devices, for example, in an imaging device that images a subject, an imaging element chip is arranged in a recess formed by: a substrate including a wiring layer and an insulating layer; and an annular frame containing a mold resin and arranged on the substrate. By bonding a lid of glass or the like to this frame with an adhesive containing sealing resin, for example, packaging is completed. In this packaged imaging device, a projection continuous along an annular circumferential direction is provided on an upper surface of the frame, in order to control a thickness of the sealing resin when the glass lid is mounted (see Cited Document 1).

### CITATION LIST

### Patent Document

Patent Document 1: Japanese Patent Application Laid-Open No. 2019-129276

### SUMMARY OF THE INVENTION

### Problems to be Solved by the Invention

However, in the imaging device described in Cited Document 1, thin sealing resin is present between the projection of the frame and the glass lid, and there is a risk that this thin sealing resin may peel off.

The present disclosure provides a semiconductor device capable of suppressing peeling of sealing resin.

### Solutions to Problems

A semiconductor device according to a first aspect of the present disclosure includes: a substrate; a frame having a wall portion that is annularly arranged on the substrate and has a plurality of projection portions on an upper surface, the frame having a groove portion provided on the upper surface of the wall portion in correspondence to each of the projection portions; a semiconductor chip arranged in a region surrounded by the wall portion on the substrate; and a lid portion arranged on the upper surface of the wall portion and sealing the semiconductor chip.

In the semiconductor device of the first aspect, the semiconductor chip may have at least one terminal, the substrate may have at least one first pad and a wiring portion connected to the first pad, and the semiconductor device may further include a wire configured to electrically connect the terminal and the first pad.

The semiconductor device of the first aspect may further include a second pad arranged on a lower surface of the substrate and electrically connected to the wiring portion.

In the semiconductor device according to the first aspect, the wall portion may have a substantially rectangular shape in plan view from an upper surface side, and the plurality of projection portions may be separately arranged on an inner peripheral side of two opposing sides of the wall portion.

In the semiconductor device according to the first aspect, the groove portion may be provided on an outer peripheral side of the wall portion with respect to the projection portion.

In the semiconductor device according to the first aspect, the groove portion may be annularly provided on the upper surface of the wall portion.

In the semiconductor device according to the first aspect, the wall portion may have a substantially rectangular shape in plan view from an upper surface side, and the plurality of projection portions may be arranged on an outer peripheral side of four corner portions of the wall portion.

In the semiconductor device according to the first aspect, the groove portion may be arranged on an inner peripheral side of the wall portion with respect to the projection portion.

In the semiconductor device according to the first aspect, an upper end portion of the projection portion may have a rounded shape in a cross section cut in a vertical direction.

In the semiconductor device according to the first aspect, an upper end portion of the projection portion may have a trapezoidal shape in a cross section cut in a vertical direction.

In the semiconductor device according to the first aspect, the wall portion may have three or more of the projection portions.

In the semiconductor device according to the first aspect, the three or more projection portions may be arranged at apex positions of a polygon in plan view of the wall portion viewed from an upper surface side.

The semiconductor device according to the first aspect may further include a bonding member that is arranged in a region where none of the projection portions are present in an upper surface portion of the wall portion and bonds the frame with the lid portion.

In the semiconductor device according to the first aspect, the bonding member may be arranged in at least a part of an inside of the groove portion.

In the semiconductor device according to the first aspect, heights from an upper surface of the substrate to upper end portions of the plurality of projection portions may be substantially equal.

In the semiconductor device according to the first aspect, the lid portion may be arranged substantially parallel to the substrate.

In the semiconductor device of the first aspect, the semiconductor chip may be an imaging element.

In the semiconductor device according to the first aspect, the lid portion may contain a material that allows light in a band including visible light to pass through.

### BRIEF DESCRIPTION OF DRAWINGS

FIG. 1A is a plan view of a semiconductor device according to a first embodiment, and FIG. 1B is a cross-sectional view taken along cross section A-A illustrated in FIG. 1A.

FIG. 2A is a plan view illustrating a manufacturing step of the semiconductor device of the first embodiment, and FIG. 2B is a cross-sectional view taken along cross section A-A illustrated in FIG. 2A.

FIG. 3A is a plan view illustrating a manufacturing step of the semiconductor device of the first embodiment, and FIG. 3B is a cross-sectional view taken along cross section A-A illustrated in FIG. 3A.

FIG. 4A is a plan view illustrating a manufacturing step of the semiconductor device of the first embodiment, and FIG. 4B is a cross-sectional view taken along cross section A-A illustrated in FIG. 4A.

FIG. 5A is a plan view illustrating a manufacturing step of the semiconductor device of the first embodiment, and FIG. 5B is a cross-sectional view taken along cross section A-A illustrated in FIG. 5A.

FIGS. 6A and 6B are views for explaining a shape around a projection portion of the semiconductor device according to the first embodiment after application of a shielding resin.

FIG. 7A is a plan view of a semiconductor device according to a second embodiment, FIG. 7B is a cross-sectional view taken along cross section A-A illustrated in FIG. 7A, and FIG. 7C is a cross-sectional view illustrating a shape around a projection portion.

FIG. 8A is a plan view of a semiconductor device according to a third embodiment, FIG. 8B is a cross-sectional view taken along cross section A-A illustrated in FIG. 8A, and FIG. 8C is a cross-sectional view illustrating a shape around a projection portion.

FIG. 9A is a plan view of a semiconductor device according to a fourth embodiment, FIG. 9B is a cross-sectional view taken along cross section A-A illustrated in FIG. 9A, and FIG. 9C is a cross-sectional view illustrating a shape around a projection portion.

FIG. 10A is a plan view of a semiconductor device according to a fifth embodiment, FIG. 10B is a cross-sectional view taken along cross section A-A illustrated in FIG. 10A, and FIG. 10C is a cross-sectional view illustrating a shape around a projection portion.

FIG. 11 is a block diagram illustrating an example of a schematic configuration of a vehicle control system.

FIG. 12 is an explanatory view illustrating an example of an installation position of a vehicle exterior information detection part and an imaging unit.

### MODE FOR CARRYING OUT THE INVENTION

Embodiments of the present disclosure are described with reference to the drawings. Although components of an imaging device and electronic apparatus are mainly described in the following embodiments, the imaging device and the electronic apparatus may have components and functions that are not illustrated or described. The following description does not exclude components and functions that are not illustrated or described.

Furthermore, the drawings referred to in the following description are drawings for illustrating the embodiments of the present disclosure and promoting understanding thereof, and shapes, dimensions, ratios and the like in the drawings might be different from actual ones for the sake of clarity.

### First Embodiment

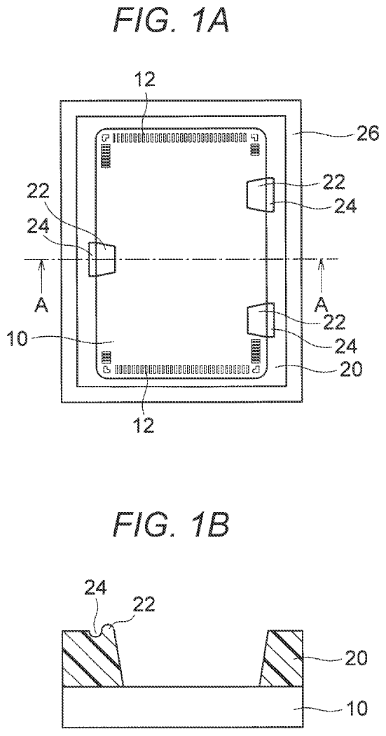

A semiconductor device according to a first embodiment will be described with reference to FIGS. 1A to 7B. FIG. 1A is a plan view of the semiconductor device according to the first embodiment before a semiconductor element is placed on a substrate, and FIG. 1B is a cross-sectional view taken along cross section A-A illustrated in FIG. 1A.

This semiconductor device of the first embodiment includes a substrate 10, and an annular frame (wall portion) 20 containing, for example, mold resin is provided on an outer peripheral portion of an upper surface of the substrate 10. The substrate 10 has a structure in which a plurality of wiring layers is stacked with an insulating layer interposed therebetween. Then, on a surface of the substrate 10, a plurality of pads 12 electrically connected to wiring of the wiring layers described above is provided. Here, “A and B are electrically connected” means that A and B may be directly connected or indirectly connected via a conductor. These pads 12 are arranged on a bottom surface of a recess surrounded by the frame 20, that is, on the upper surface of the substrate 10.

This frame 20 has a substantially rectangular shape, and is provided with a plurality of (three in FIG. 1A) projection portions 22 on an innermost peripheral portion of the upper surface. These projection portions 22 are provided on two opposing sides, for example, long sides, of an upper surface of the frame 20. Then, in the present embodiment, as illustrated in FIG. 1B, a tip end of the projection portion 22 has a rounded shape. Furthermore, as illustrated in FIG. 1A, these projection portions 22 are configured to project inward from an inner peripheral portion of the frame 20. Note that three or more projection portions 22 are preferably provided, and three projection portions 22 are more preferably provided in order to place and pressurize a lid portion to be described later.

On the upper surface of the frame 20, a groove 24 is provided on an outer side of the projection portion 22 in correspondence to the projection portion 22. Furthermore, a region 26 to be applied with shielding resin is provided on an outer peripheral portion of the upper surface of the frame 20.

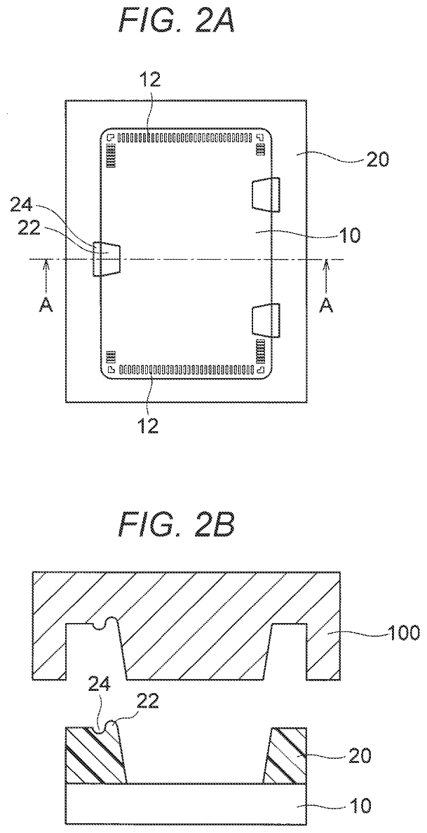

Next, a semiconductor device manufacturing method according to the first embodiment will be described with reference to FIGS. 2A to 5B. First, as illustrated in FIGS. 2A and 2B, mold resin is applied to an outer peripheral portion of a surface of the substrate 10, and a mold 100 is pressed against the substrate 10 via the mold resin, and for example, heat is applied to cure the mold resin. Note that, when the mold resin is a photocurable resin, the resin is cured by irradiating the applied resin with light. As a result, the frame 20 containing the mold resin is formed on an outer peripheral portion of the surface of the substrate 10. At this time, since the mold 100 is provided with recesses at positions corresponding to the plurality of projection portions 22, the plurality of projection portions 22 is formed on an innermost peripheral portion of the upper surface of the formed frame 20. FIG. 2A is a plan view illustrating a manufacturing step, and FIG. 2B is a cross-sectional view taken along cross section A-A illustrated in FIG. 2A.

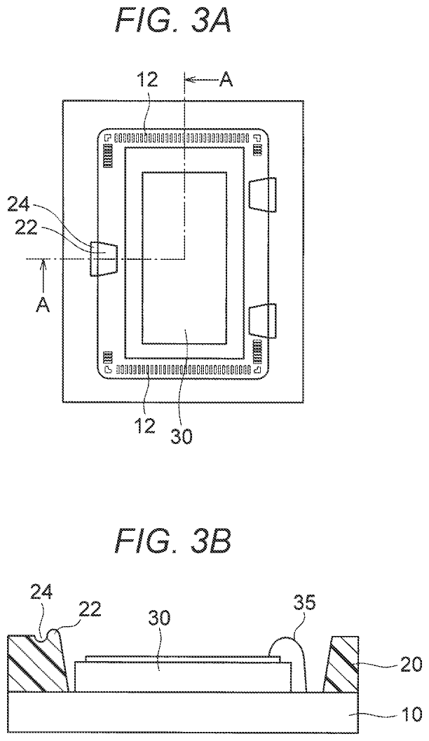

Subsequently, as illustrated in FIGS. 3A and 3B, a semiconductor element 30 is joined to a surface of a recess surrounded by the substrate 10 and the frame 20, by using an adhesive (not illustrated). Thereafter, a terminal of the semiconductor element 30 and the pad 12 of the substrate 10 are connected by a bonding wire 35 by using a wire bonding method. FIG. 3A is a plan view illustrating a manufacturing step, and FIG. 3B is a cross-sectional view taken along cross section A-A illustrated in FIG. 3A.

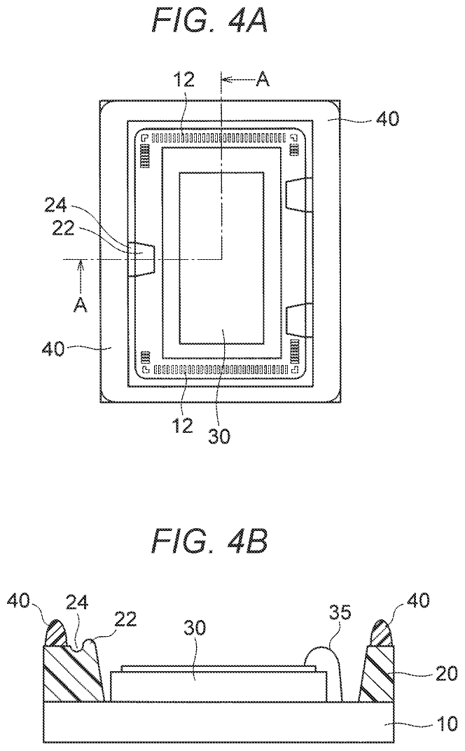

Next, as illustrated in FIGS. 4A and 4B, an adhesive, for example, sealing resin 40 is applied to the region 26 to which the resin is applied in the outer peripheral portion of the frame 20. A dispenser is used to apply this sealing resin 40. FIG. 4A is a plan view illustrating a manufacturing step, and FIG. 4B is a cross-sectional view taken along cross section A-A illustrated in FIG. 4A.

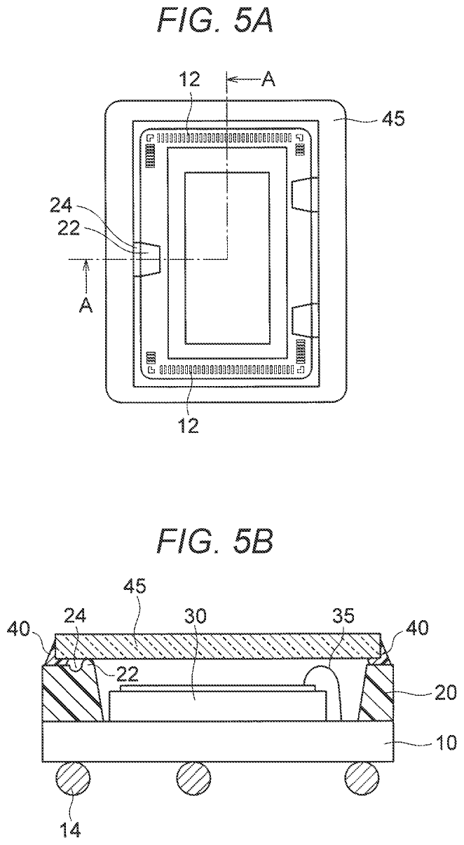

Next, as illustrated in FIGS. 5A and 5B, a lid portion 45 is positioned and placed on the upper surface of the frame 20 applied with the resin 40. Note that, in a case where the semiconductor element 30 is an imaging element, that is, in a case where the semiconductor device is an imaging device, a material that transmits light beams including visible light, for example, glass is used for the lid portion 45. FIG. 4A is a plan view illustrating a manufacturing step, and FIG. 4B is a cross-sectional view taken along cross section A-A illustrated in FIG. 4A. In this way, an uncompleted semiconductor device is formed. Subsequently, the semiconductor device described above is conveyed into a pressure container, and pressure is applied. This pressure can be applied, for example, by gradually increasing the pressure from atmospheric pressure to pressure of 0.042 MPa. Subsequently, bonding is performed. The bonding can be performed by, for example, heating the semiconductor device in a pressurized state to cure the adhesive 40. The heating can be performed, for example, by gradually raising a temperature from room temperature to a temperature of 130° C. After the adhesive 40 is cured, heating is stopped. Note that, in the step described above, the projection portion 22 of the frame 20 may or may not be in contact with the lid portion 45.

Next, the pressure in the pressure container is reduced to the atmospheric pressure. Subsequently, the temperature in the pressure container is cooled to a temperature near the room temperature. Thereafter, spherical solders (pads) 14 are arranged on a back surface of the substrate 10. These solders 14 are joined to the wiring layer of the substrate 10. In a case where a circuit for driving the semiconductor element is mounted on an external circuit substrate, the solder 14 is connected to a pad formed on the external circuit substrate. In this way, an electric signal is transmitted between the substrate 10 and the circuit substrate via the solder 14. Through the above steps, a semiconductor device (semiconductor package) can be manufactured. Note that the semiconductor device manufacturing method is not limited to the example described above. For example, the pressurizing step and the heating step can be performed simultaneously in the pressure container. Furthermore, the heating can be stopped after the pressure is reduced to the atmospheric pressure.

Furthermore, a semiconductor element for in-vehicle application is to be used in a relatively wide temperature range. In a case where the semiconductor device (or the imaging device) of the first embodiment is used in the in-vehicle application, a large stress is repeatedly applied to the semiconductor package. AEC-Q100 is applied as a reliability test to the semiconductor element supposed to be used in such a severe environment. In this AEC-Q100, for example, a 1000-cycle test is carried out at −55° C. to 125° C. as a temperature cycle test.

For example, glass which is an inorganic material is used as the lid portion 45. In a case where an organic material such as resin is used as the substrate 10, it is assumed that the semiconductor device is bent in a downward convex shape as the temperature rises. This is because an elongation amount of the substrate 10 is larger than that of the lid portion 45. Whereas, when the temperature decreases, it is assumed that the semiconductor device bends in an upward convex shape. When the semiconductor device is deformed in this way, stress concentrates on a peripheral portion of the semiconductor device, a strong stress is applied to the adhesive 40, and a thin resin film between the lid portion 45 and the frame 20 is peeled off.

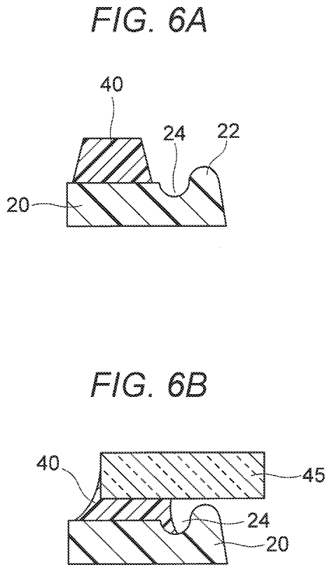

However, in the semiconductor device of the present embodiment, the plurality of projection portions 22 is provided on the innermost peripheral portion of the frame 20. Therefore, as illustrated in FIGS. 6A and 6B, in the adhesive 40 applied to the upper surface of the frame 20, when the lid portion 45 is placed on the upper surface of the frame 20 and pressurized, a thick film of the adhesive 40 is present between the lid portion 45 and the upper surface of the frame 20. FIG. 6A is a cross-sectional view when the adhesive 40 is applied to the upper surface of the frame 20, and FIG. 6B is a cross-sectional view after the lid portion 45 is placed and pressurized.

As described above, in the present embodiment, after the pressurizing step, a thick film of the adhesive 40 is present between the lid portion 45 and the adhesive 40, and thin resin (a film of the adhesive is not present between the lid portion 45 and the frame 20. Therefore, a stress applied to the adhesive 40 at the time of manufacturing or use is applied to the adhesive 40 including the thick resin layer, and it is possible to suppress peeling of the adhesive 40. Furthermore, on the upper surface of the frame 20, the groove 24 is provided on an outer side of the projection portion 22 in correspondence to the projection portion 22. Therefore, as illustrated in FIG. 6B, the pressurized resin (adhesive) 40 enters the groove 24, but can be suppressed from rising up to the projection portion 22. Therefore, the resin 40 can be prevented from flowing to an inner side of the frame 20, and a highly reliable semiconductor device can be obtained.

### Second Embodiment

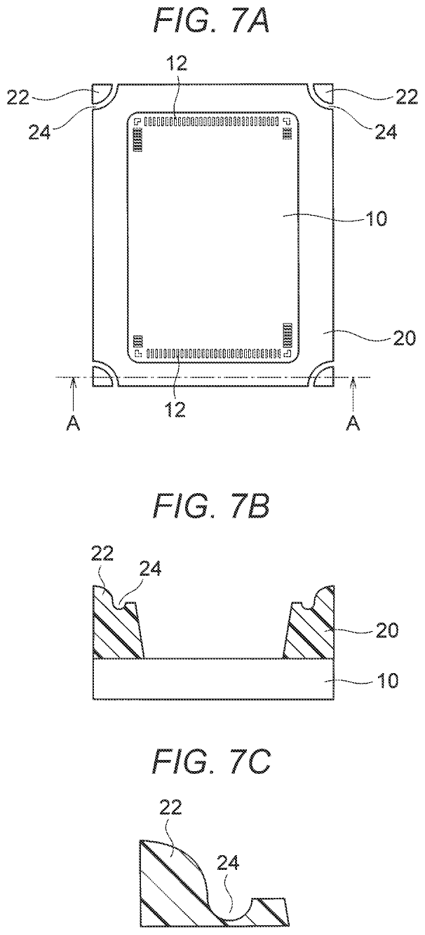

A semiconductor device according to a second embodiment will be described with reference to FIGS. 7A to 7C. FIG. 7A is a plan view of the semiconductor device according to the second embodiment before a semiconductor element is placed, FIG. 7B is a cross-sectional view taken along section A-A illustrated in FIG. 7A, and FIG. 7C is an enlarged view of a projection portion 22.

This semiconductor device of the second embodiment is different from the semiconductor device of the first embodiment illustrated in FIG. 1A in a position of the projection portion 22 provided on an upper surface of a frame 20. As illustrated in FIG. 7A, this semiconductor device according to the second embodiment has a configuration in which the projection portion 22 is provided at four corner portions (corners) of the substantially rectangular frame 20 containing mold resin and provided on an outer peripheral portion of a substrate 10. As illustrated in FIG. 7C, the projection portion 22 has a shape in which a height smoothly decreases from an outer peripheral side toward an inner peripheral side. Then, in correspondence to these projection portions 22, a groove 24 is provided on an inner side of each projection portion 22 on the upper surface of the frame 20 (see FIG. 7A).

Similarly to the first embodiment, the semiconductor element is joined to a bottom surface of a recess surrounded by the substrate 10 and the frame 20 configured as described above, by using an adhesive (not illustrated) with the semiconductor element. Thereafter, a terminal of the semiconductor element and a pad 12 of the substrate are connected by a bonding wire using a wire bonding method (see, for example, FIG. 3B).

Next, an adhesive, for example, sealing resin is applied to a region along an inner peripheral portion of the upper surface of the frame 20. Thereafter, similarly to the description with reference to FIGS. 5A and 5B of the first embodiment, a lid portion 45 is positioned and placed on the upper surface of the frame 20 applied with the resin 40. Thereafter, the semiconductor device is manufactured using steps similar to those in the case described in the first embodiment.

Similarly to the first embodiment, in the semiconductor device of the second embodiment configured as described above, after the pressurizing step, a thick film of the adhesive 40 is present between the lid portion and the adhesive, and thin resin (a film of the adhesive) is not present between the lid portion and the frame. Therefore, a stress applied to the adhesive at the time of manufacturing or use is applied to the adhesive including the thick resin layer, and it is possible to suppress peeling of the adhesive. Furthermore, on the upper surface of the frame, since a groove is provided on an inner side of the projection portion in correspondence to the projection portion, the pressed resin (adhesive) enters the groove, but can be suppressed from rising up to the projection portion, similarly to the case illustrated in FIG. 6B. Therefore, it is also possible to suppress the resin from flowing to an outer side of the frame, and a highly reliable semiconductor device can be obtained.

### Third Embodiment

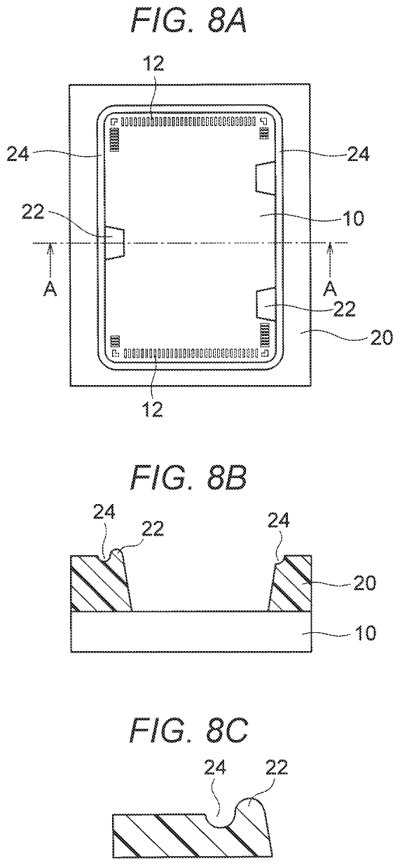

A semiconductor device according to a third embodiment will be described with reference to FIGS. 8A to 8C. FIG. 8A is a plan view of the semiconductor device according to the third embodiment before a semiconductor element is placed, FIG. 8B is a cross-sectional view taken along cross section A-A illustrated in FIG. 8A, and FIG. 8C is an enlarged view of a projection portion 22.

This semiconductor device of the third embodiment has a configuration in which the groove 24 is provided along an inner periphery of an upper surface of the frame 20 in the semiconductor device of the first embodiment illustrated in FIGS. 1A to 6B. In subsequent steps, steps similar to those of the first embodiment illustrated in FIGS. 3A to 5B are performed to manufacture the semiconductor device of the third embodiment.

In this semiconductor device of the third embodiment, a thick film of the adhesive 40 is present between the lid portion 45 and the adhesive 40, and thin resin (a film of the adhesive is not present between the lid portion 45 and the frame 20. Therefore, a stress applied to the adhesive 40 at the time of manufacturing or use is applied to the adhesive 40 including the thick resin layer, and it is possible to suppress peeling of the adhesive 40. Furthermore, on the upper surface of the frame 20, the groove 24 is provided on an outer side of the projection portion 22 in correspondence to the projection portion 22 over the entire circumference. Therefore, as illustrated in FIG. 6B, the pressurized resin (adhesive) 40 enters the groove 24, but can be suppressed from rising up to the projection portion 22. Therefore, the resin 40 can be prevented from flowing to an inner side of the frame 20, and a more highly reliable semiconductor device than that of the first embodiment can be obtained.

### Fourth Embodiment

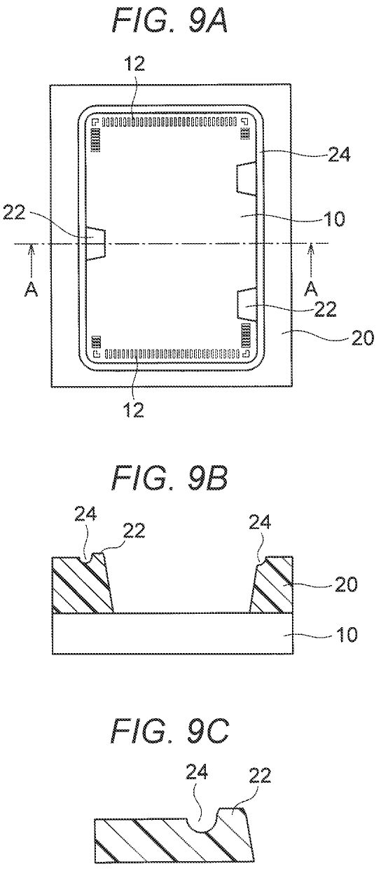

A semiconductor device according to a fourth embodiment will be described with reference to FIGS. 9A to 9C. FIG. 9A is a plan view of the semiconductor device according to the fourth embodiment before a semiconductor element is placed, FIG. 9B is a cross-sectional view taken along cross section A-A illustrated in FIG. 9A, and FIG. 9C is an enlarged view of a projection portion 22.

This semiconductor device of the fourth embodiment has a configuration in which a cross-sectional shape of the projection portion 22 is a trapezoidal shape as illustrated in FIG. 9C, in the semiconductor device of the third embodiment illustrated in FIGS. 8A to 8B. In subsequent steps, steps similar to those of the first embodiment illustrated in FIGS. 3A to 5B are performed to manufacture the semiconductor device of the third embodiment.

In the semiconductor device of the fourth embodiment, a thick film of the adhesive 40 is present between the lid portion 45 and the adhesive 40, and thin resin (a film of the adhesive is not present between the lid portion 45 and a frame 20. Therefore, a stress applied to the adhesive 40 at the time of manufacturing or use is applied to the adhesive 40 including the thick resin layer, and it is possible to suppress peeling of the adhesive 40. Furthermore, on the upper surface of the frame 20, the groove 24 is provided on an outer side of the projection portion 22 in correspondence to the projection portion 22 over the entire circumference. Therefore, as illustrated in FIG. 6B, the pressurized resin (adhesive) 40 enters the groove 24, but can be suppressed from rising up to the projection portion 22. Therefore, the resin 40 can be prevented from flowing to an inner side of the frame 20, and a more highly reliable semiconductor device than that of the first embodiment can be obtained.

### Fifth Embodiment

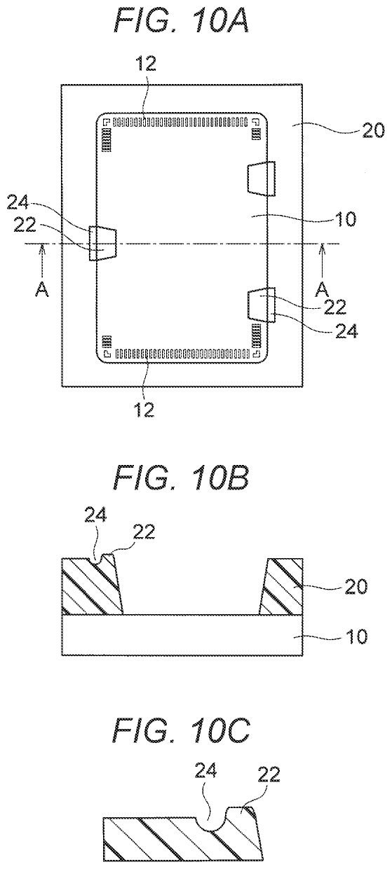

A semiconductor device according to a fifth embodiment will be described with reference to FIGS. 10A to 10C. FIG. 10A is a plan view of the semiconductor device according to the fifth embodiment before a semiconductor element is placed, FIG. 10B is a cross-sectional view taken along cross section A-A illustrated in FIG. 10A, and FIG. 10C is an enlarged view of a projection portion 22.

This semiconductor device of the fifth embodiment has a configuration in which a cross-sectional shape of the projection portion 22 is a trapezoidal shape as illustrated in FIG. 9C, in the semiconductor device of the first embodiment illustrated in FIGS. 1A to 6B. In subsequent steps, steps similar to those of the first embodiment illustrated in FIGS. 3A to 5B are performed to manufacture the semiconductor device of the fifth embodiment.

In this semiconductor device of the fifth embodiment, a thick film of the adhesive 40 is present between the lid portion 45 and the adhesive 40, and thin resin (a film of the adhesive is not present between the lid portion 45 and a frame 20. Therefore, a stress applied to the adhesive 40 at the time of manufacturing or use is applied to the adhesive 40 including the thick resin layer, and it is possible to suppress peeling of the adhesive 40. Furthermore, on the upper surface of the frame 20, the groove 24 is provided on an outer side of the projection portion 22 in correspondence to the projection portion 22 over the entire circumference. Therefore, as illustrated in FIG. 6B, the pressurized resin (adhesive) 40 enters the groove 24, but can be suppressed from rising up to the projection portion 22. Therefore, the resin 40 can be prevented from flowing to an inner side of the frame 20, and a more highly reliable semiconductor device than that of the first embodiment can be obtained.

### Application Example

The technology according to the present disclosure can be applied to various products. For example, the technology (for example, an imaging device) according to the present disclosure may be implemented as a device to be mounted on any type of mobile objects such as vehicles, electric vehicles, hybrid electric vehicles, motorcycles, bicycles, personal mobilities, airplanes, drones, ships, robots, construction machines, and agricultural machines (tractors).

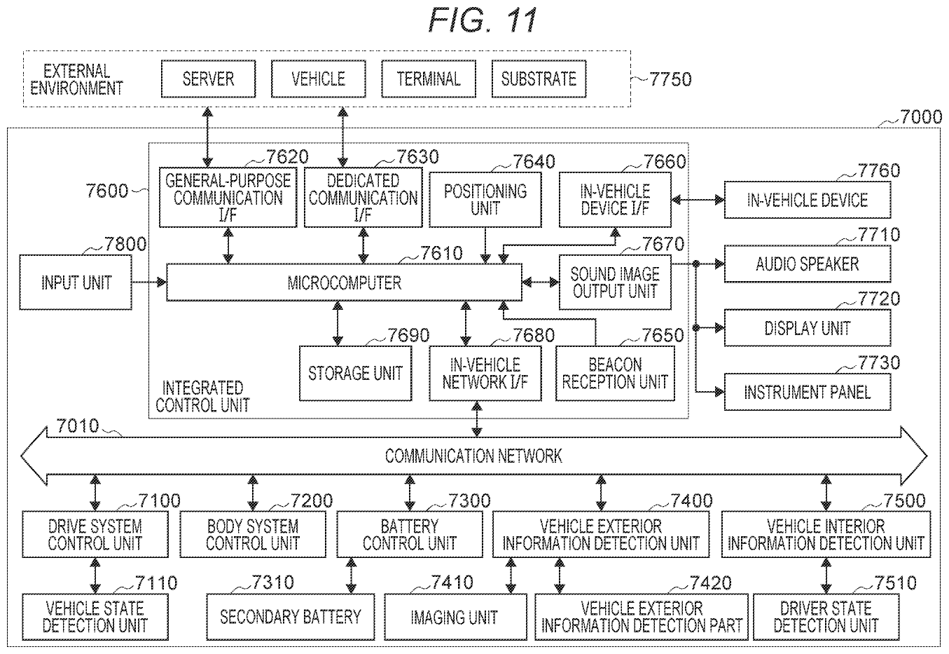

FIG. 11 is a block diagram illustrating a schematic configuration example of a vehicle control system 7000, which is an example of a mobile object control system to which the technology according to the present disclosure may be applied. The vehicle control system 7000 includes a plurality of electronic control units connected via a communication network 7010. In the example illustrated in FIG. 11, the vehicle control system 7000 includes a drive system control unit 7100, a body system control unit 7200, a battery control unit 7300, a vehicle exterior information detection unit 7400, a vehicle interior information detection unit 7500, and an integrated control unit 7600. The communication network 7010 connecting the plurality of control units may be, for example, an in-vehicle communication network compliant with any of standards such as controller area network (CAN), local interconnect network (LIN), local area network (LAN), and FlexRay (registered trademark).

Each control unit includes a microcomputer that performs arithmetic processing according to various programs, a storage unit that stores programs executed by the microcomputer, parameters used for various calculations, or the like, and a drive circuit that drives various devices to be controlled. Each control unit includes a network I/F for performing communication with the other control units via the communication network 7010, and includes a communication I/F for performing communication with devices, sensors, or the like inside and outside a vehicle by wired or wireless communication. In FIG. 11, a microcomputer 7610, a general-purpose communication I/F 7620, a dedicated communication I/F 7630, a positioning unit 7640, a beacon reception unit 7650, an in-vehicle device I/F 7660, a sound image output unit 7670, an in-vehicle network I/F 7680, and a storage unit 7690 are illustrated as a functional configuration of the integrated control unit 7600. Similarly, the other control units include microcomputers, communication I/Fs, storage units, and the like.

The drive system control unit 7100 controls operation of devices related to the drive system of the vehicle according to various programs. For example, the drive system control unit 7100 serves as a control device of a driving force generating device for generating driving force of the vehicle such as an internal combustion engine, a driving motor or the like, a driving force transmitting mechanism for transmitting the driving force to wheels, a steering mechanism that adjusts a rudder angle of the vehicle, a braking device that generates braking force of the vehicle and the like. The drive system control unit 7100 may have a function as a control device such as an antilock brake system (ABS) or an electronic stability control (ESC).

A vehicle state detection unit 7110 is connected to the drive system control unit 7100. The vehicle state detection unit 7110 includes, for example, a gyro sensor that detects an angular velocity of axial rotational movement of a vehicle body, an acceleration sensor that detects acceleration of the vehicle, or at least one of sensors for detecting an operation amount of an accelerator pedal, an operation amount of a brake pedal, a steering angle of a steering wheel, an engine speed, a wheel rotational speed or the like. The drive system control unit 7100 performs arithmetic processing using a signal input from the vehicle state detection unit 7110, and controls an internal combustion engine, a driving motor, an electric power steering device, a brake device, or the like.

The body system control unit 7200 controls operation of various devices mounted on the vehicle body in accordance with the various programs. For example, the body system control unit 7200 serves as a control device of a keyless entry system, a smart key system, a power window device, or various lights such as a head light, a backing light, a brake light, a blinker, a fog light or the like. In this case, a radio wave transmitted from a portable device that substitutes for a key or signals of various switches may be input to the body system control unit 7200. The body system control unit 7200 receives an input of these radio waves or signals, and controls a door lock device, a power window device, a lamp, and the like of the vehicle.

The battery control unit 7300 controls a secondary battery 7310 that is a power supply source of the driving motor according to the various programs. For example, information such as battery temperature, a battery output voltage, or remaining battery capacity is input to the battery control unit 7300 from the battery device provided with the secondary battery 7310. The battery control unit 7300 performs arithmetic processing using these signals, and performs temperature regulation control of the secondary battery 7310 or a cooling device provided in the battery device, or the like.

The vehicle exterior information detection unit 7400 detects information external to the vehicle on which the vehicle control system 7000 is mounted. For example, the vehicle exterior information detection unit 7400 is connected to at least one of an imaging unit 7410 or a vehicle exterior information detection part 7420. The imaging unit 7410 includes at least one of a time of flight (ToF) camera, a stereo camera, a monocular camera, an infrared camera, or other cameras. The vehicle exterior information detection part 7420 includes, for example, at least one of an environmental sensor for detecting current weather or meteorological phenomenon, or an ambient information detection sensor for detecting other vehicles, obstacles, pedestrians or the like around the vehicle on which the vehicle control system 7000 is mounted.

The environment sensor may be, for example, at least one of a raindrop sensor that detects rainy weather, a fog sensor that detects fog, a sunshine sensor that detects a sunlight degree, or a snow sensor that detects snowfall. The ambient information detection sensor may be at least one of an ultrasonic sensor, a radar device, or light detection and ranging, laser imaging detection and ranging (LIDAR) device. The imaging unit 7410 and the vehicle exterior information detection part 7420 may be provided as independent sensors or devices, or may be provided as a device in which a plurality of sensors or devices is integrated.

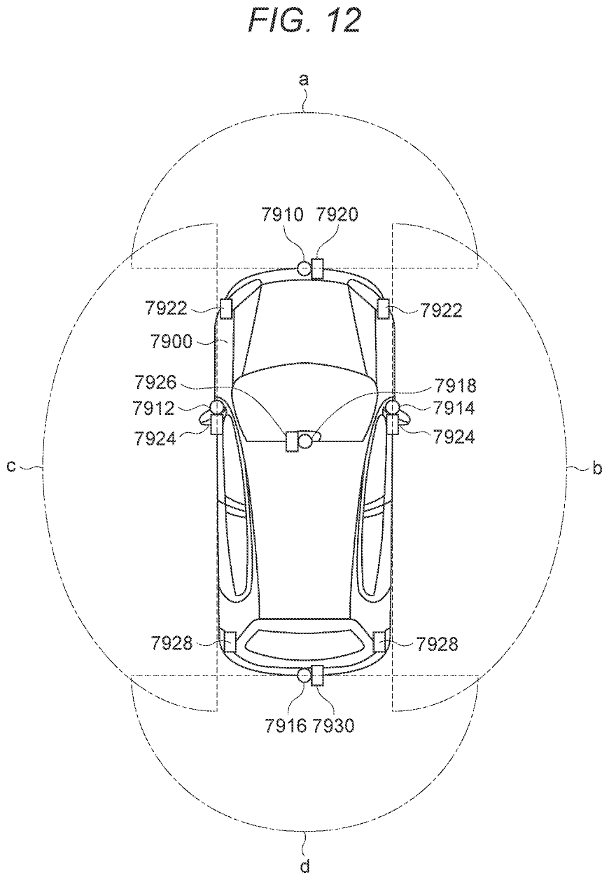

Here, FIG. 12 illustrates an example of installation positions of the imaging unit 7410 and the vehicle exterior information detection part 7420. Imaging units 7910, 7912, 7914, 7916, 7918 are provided in, for example, at least one of a front nose, a side mirror, a rear bumper, a rear door, or an upper part of a windshield in a cabin of a vehicle 7900. The imaging unit 7910 provided on the front nose and the imaging unit 7918 provided in the upper portion of the windshield in the cabin principally obtain images in front of the vehicle 7900. The imaging units 7912 and 7914 provided on the side mirrors principally obtain images of the sides of the vehicle 7900. The imaging unit 7916 provided on the rear bumper or the rear door principally obtains an image behind the vehicle 7900. The imaging unit 7918 provided on the upper part of the windshield in the cabin is mainly used for detecting a preceding vehicle, a pedestrian, an obstacle, a traffic signal, a traffic sign, a lane, or the like.

Note that FIG. 12 illustrates an example of an imaging range of each of the imaging units 7910, 7912, 7914, and 7916. An imaging range a indicates an imaging range of the imaging unit 7910 provided in the front nose, imaging ranges b and c indicate imaging ranges of the imaging units 7912 and 7914 provided in the side mirrors, respectively, and an imaging range d indicates an imaging range of the imaging unit 7916 provided in the rear bumper or the rear door. A bird's-eye image of the vehicle 7900 as viewed from above is obtained by superimposing image data imaged by the imaging units 7910, 7912, 7914, and 7916, for example.

Vehicle exterior information detection parts 7920, 7922, 7924, 7926, 7928, and 7930 provided on the front, rear, side, corner, and the upper portion of the windshield in the cabin of the vehicle 7900 may be ultrasonic sensors or radar devices, for example. The vehicle exterior information detection parts 7920, 7926, and 7930 provided on the front nose, the rear bumper, the rear door, and the upper portion of the windshield in the cabin of the vehicle 7900 may be, for example, the LIDAR devices. These vehicle exterior information detection parts 7920 to 7930 are mainly used for detecting a preceding vehicle, a pedestrian, an obstacle, or the like.

Returning to FIG. 11, the description will be continued. The vehicle exterior information detection unit 7400 causes the imaging unit 7410 to capture an image outside the vehicle, and receives data of the captured image. Furthermore, the vehicle exterior information detection unit 7400 receives detection information from the vehicle exterior information detection part 7420 connected thereto. In a case where the vehicle exterior information detection part 7420 is the ultrasonic sensor, the radar device, or the LIDAR device, the vehicle exterior information detection unit 7400 transmits ultrasonic waves, electromagnetic waves or the like, and receives information of received reflected wave. The vehicle exterior information detection unit 7400 may perform detection processing of objects such as a person, a vehicle, an obstacle, a sign, or a character on a road surface or distance detection processing on the basis of the received image. The vehicle exterior information detection unit 7400 may perform environment recognition processing for recognizing rainfall, fog, road surface conditions or the like on the basis of the received information. The vehicle exterior information detection unit 7400 may calculate a distance to an object outside the vehicle on the basis of the received information.

Furthermore, the vehicle exterior information detection unit 7400 may perform an image recognition process or a distance detection process of recognizing a person, a vehicle, an obstacle, a sign, or a character on a road surface, or the like on the basis of the received image data. The vehicle exterior information detection unit 7400 may perform processing such as distortion correction or alignment on the received image data, and combine the image data imaged by different imaging units 7410 to generate an overlooking image or a panoramic image. The vehicle exterior information detection unit 7400 may perform viewpoint conversion processing using the image data imaged by the different imaging units 7410.

The vehicle interior information detection unit 7500 detects information in the vehicle. The vehicle interior information detection unit 7500 is connected to, for example, a driver state detection unit 7510 for detecting a state of a driver. The driver state detection unit 7510 may include a camera that images the driver, a biometric sensor that detects biometric information of the driver, a microphone that collects sound in the cabin or the like. The biometric sensor is provided, for example, on a seat surface, a steering wheel or the like, and detects biometric information of a passenger sitting on the seat or the driver holding the steering wheel. The vehicle interior information detection unit 7500 may calculate a driver's fatigue level or concentration level or may determine whether the driver is not dozing on the basis of detection information input from the driver state detection unit 7510. The vehicle interior information detection unit 7500 may perform processing such as noise canceling processing or the like on the collected audio signal.

The integrated control unit 7600 controls the overall operation in the vehicle control system 7000 according to various programs. An input unit 7800 is connected to the integrated control unit 7600. The input unit 7800 is realized by a device that may be operated by the passenger to input, such as a touch panel, a button, a microphone, a switch, or a lever, for example. To the integrated control unit 7600, data obtained by audio recognition of audio input by the microphone may be input. The input unit 7800 may be, for example, a remote control device using infrared rays or other radio waves, or may be an external connection device such as a mobile phone or a personal digital assistant (PDA) that supports the operation of the vehicle control system 7000. The input unit 7800 may be, for example, a camera, and in that case, the passenger may input information by gesture. Alternatively, data obtained by detecting movement of a wearable device worn by the passenger may be input. Moreover, the input unit 7800 may include, for example, an input control circuit and the like that generates an input signal on the basis of the information input by the passenger and the like using the input unit 7800 described above and outputs to the integrated control unit 7600. The passenger or the like operates the input unit 7800 to input various data to the vehicle control system 7000 or indicates processing operation.

The storage unit 7690 may include a read only memory (ROM) that stores various programs to be executed by the microcomputer, and a random access memory (RAM) that stores various parameters, operation results, sensor values, and the like. Furthermore, the storage unit 7690 may be realized by a magnetic storage device such as a hard disc drive (HDD), a semiconductor storage device, an optical storage device, a magneto-optical storage device, or the like.

The general-purpose communication I/F 7620 is a generic communication I/F that mediates communication with various apparatuses present in an external environment 7750. The general-purpose communication I/F 7620 may implement a cellular communication protocol such as global system of mobile communications (GSM (registered trademark)), WiMAX (registered trademark), long term evolution (LTE (registered trademark)), or LTE-advanced (LTE-A), or other wireless communication protocols such as wireless LAN (also referred to as Wi-Fi (registered trademark)), Bluetooth (registered trademark) and the like. The general-purpose communication I/F 7620 may be connected to a device (for example, an application server or a control server) present on an external network (for example, the Internet, a cloud network, or an operator-specific network) via, for example, a base station or an access point. In addition, the general-purpose communication I/F 7620 may be connected to a terminal (for example, a terminal of a driver, a pedestrian, or a store, or a machine type communication (MTC) terminal) existing in the vicinity of the vehicle using, for example, a peer to peer (P2P) technology.

The dedicated communication I/F 7630 is a communication I/F that supports a communication protocol designed for use in vehicles. The dedicated communication I/F 7630 may implement standard protocols such as wireless access in vehicle environment (WAVE) that is a combination of lower-layer IEEE802.11p and upper-layer IEEE1609, dedicated short range communications (DSRC), or cellular communication protocol, for example. The dedicated communication I/F 7630 typically performs V2X communication that is a concept including one or more of vehicle-to-vehicle communication, vehicle-to-infrastructure communication, vehicle-to-home communication, and vehicle-to-pedestrian communication.

The positioning unit 7640 receives a GNSS signal from a global navigation satellite system (GNSS) satellite (for example, a GPS signal from a global positioning system (GPS) satellite) to execute positioning, and generates positional information including the latitude, longitude, and altitude of the vehicle, for example. Note that, the positioning unit 7640 may specify a current position by exchanging signals with a wireless access point, or may obtain position information from a terminal such as a portable phone, PHS, or smartphone having a positioning function.

The beacon reception unit 7650, for example, receives radio waves or electromagnetic waves transmitted from a radio station installed on a road or the like, and thereby obtains information about the current position, congestion, a closed road, a necessary time, or the like. Note that the function of the beacon reception unit 7650 may be included in the dedicated communication I/F 7630 described above.

The in-vehicle device I/F 7660 is a communication interface that mediates a connection between the microcomputer 7610 and various in-vehicle devices 7760 existing inside the vehicle. The in-vehicle device I/F 7660 may establish a wireless connection using a wireless communication protocol such as wireless LAN, Bluetooth (registered trademark), near field communication (NFC), or wireless USB (WUSB). Furthermore, the in-vehicle device I/F 7660 may establish a wired connection such as universal serial bus (USB), high-definition multimedia interface (HDMI (registered trademark)), or mobile high-definition link (MHL) via a connection terminal (and a cable if necessary) not illustrated. The in-vehicle devices 7760 may include, for example, at least one of a mobile device or a wearable device that the passenger has, or an information device carried in or attached to the vehicle. Furthermore, the in-vehicle devices 7760 may include a navigation device that searches for a route to an arbitrary destination. The in-vehicle device I/F 7660 exchanges control signals or data signals with these in-vehicle devices 7760.

The in-vehicle network I/F 7680 is an interface that mediates communication between the microcomputer 7610 and the communication network 7010. The in-vehicle network I/F 7680 transmits and receives signals and the like according to a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning unit 7640, the beacon reception unit 7650, the in-vehicle device I/F 7660, or the in-vehicle network I/F 7680. For example, the microcomputer 7610 may calculate a control target value of the driving force generating device, the steering mechanism, or the braking device on the basis of the obtained information inside and outside the vehicle and output a control instruction to the drive system control unit 7100. For example, the microcomputer 7610 may perform cooperative control for realizing functions of advanced driver assistance system (ADAS) including collision avoidance or impact attenuation of the vehicle, following travel based on the distance between the vehicles, vehicle speed maintaining travel, vehicle collision warning, vehicle lane departure warning or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a peripheral structure or a person on the basis of the information obtained by means of at least one of the general-purpose communication I/F 7620, dedicated communication I/F 7630, positioning unit 7640, beacon reception unit 7650, in-vehicle device I/F 7660, or in-vehicle network I/F 7680 and create local map information including peripheral information of the vehicle current position. Furthermore, the microcomputer 7610 may generate a warning signal by predicting a danger such as vehicle collision, approach of a pedestrian and the like or entry to a closed road on the basis of the obtained information. The warning signal may be, for example, a signal for generating a warning sound or lighting a warning lamp.

The sound image output unit 7670 transmits an output signal of at least one of a sound or an image to an output device capable of visually or auditorily giving information to an occupant of the vehicle or the outside of the vehicle. In the example of FIG. E1, an audio speaker 7710, a display unit 7720, and an instrument panel 7730 are exemplified as the output device. The display unit 7720 may include, for example, at least one of an on-board display or a head-up display. The display unit 7720 may have an augmented reality (AR) display function. In addition to these devices, the output device may be other devices such as a headphone, a wearable device such as an eyeglass-type display worn by the passenger, a projector, or light. In a case where the output device is the display device, the display device visually displays results obtained by various types of processing performed by the microcomputer 7610 or information received from other control units in various formats such as text, image, table, and graph. Furthermore, in a case where the output device is an audio output device, the audio output device converts an audio signal including reproduced audio data, acoustic data or the like into an analog signal and outputs the aurally.

Note that in the example illustrated in FIG. 11, at least two control units connected via the communication network 7010 may be integrated as one control unit. Alternatively, each control unit may be configured by a plurality of control units. Moreover, the vehicle control system 7000 may be provided with another control unit not illustrated. Furthermore, in the above description, a part of or all of the functions of any of the control units may be assigned to other control units. That is, as long as information is transmitted and received via the communication network 7010, predetermined arithmetic processing may be performed by any control unit. Similarly, a sensor or a device connected to any control unit may be connected to another control unit, and a plurality of control units may transmit/receive detection information to/from each other via the communication network 7010.

The embodiments of the present disclosure have been described above in detail with reference to the accompanying drawings, but the technical scope of the present disclosure is not limited to such examples. It is clear that one of ordinary skill in the technical field of the present disclosure may conceive of various modifications and corrections within the scope of the technical idea recited in claims. It is understood that they also naturally belong to the technical scope of the present disclosure.

Furthermore, the effects described in the present specification are merely exemplary or illustrative, and not restrictive. That is, the technology according to the present disclosure may provide other effects that are apparent to those skilled in the art from the description of the present specification, in addition to or instead of the effects described above.

Note that the following configurations also belong to the technical scope of the present disclosure.

(1) A semiconductor device including: a substrate; a frame having a wall portion that is annularly arranged on the substrate and has a plurality of projection portions on an upper surface, the frame having a groove portion provided on the upper surface of the wall portion in correspondence to each of the projection portions; a semiconductor chip arranged in a region surrounded by the wall portion on the substrate; and a lid portion arranged on the upper surface of the wall portion and sealing the semiconductor chip.

(2) The semiconductor device according to (1), in which the semiconductor chip has at least one terminal, the substrate has at least one first pad and a wiring portion connected to the first pad, and the semiconductor device further includes a wire configured to electrically connect the terminal and the first pad.

(3) The semiconductor device according to (2), further including a second pad arranged on a lower surface of the substrate and electrically connected to the wiring portion.

(4) The semiconductor device according to any one of (1) to (3), in which the wall portion has a substantially rectangular shape in plan view from an upper surface side, and the plurality of projection portions is separately arranged on an inner peripheral side of two opposing sides of the wall portion.

(5) The semiconductor device according to any one of (1) to (4), in which the groove portion is provided on an outer peripheral side of the wall portion with respect to each of the projection portions.

(6) The semiconductor device according to any one of (1) to (3), in which the groove portion is annularly provided on the upper surface of the wall portion.

(7) The semiconductor device according to any one of (1) to (3), in which the wall portion has a substantially rectangular shape in plan view from an upper surface side, and the plurality of projection portions is arranged on an outer peripheral side of four corner portions of the wall portion.

(8) The semiconductor device according to (7), in which the groove portion is arranged on an inner peripheral side of the wall portion with respect to each of the projection portions.

(9) The semiconductor device according to any one of (1) to (8), in which an upper end portion of each of the projection portions has a rounded shape in a cross section cut in a vertical direction.

(10) The semiconductor device according to any one of (1) to (8), in which an upper end portion of each of the projection portions has a trapezoidal shape in a cross section cut in a vertical direction.

(11) The semiconductor device according to any one of (1) to (10), in which the wall portion has three or more of the projection portions.

(12) The semiconductor device according to (11), in which the three or more projection portions are arranged at apex positions of a polygon in plan view of the wall portion viewed from an upper surface side.

(13) The semiconductor device according to (11), further including a bonding member arranged in a region where none of the projection portions are present in an upper surface portion of the wall portion, the bonding member bonding the frame and the lid portion.

(14) The semiconductor device according to (13), in which the bonding member is arranged in at least a part of an inside of the groove portion.

(15) The semiconductor device according to any one of (1) to (14), in which heights from an upper surface of the substrate to upper end portions of the plurality of projection portions are substantially equal.

(16) The semiconductor device according to any one of (1) to (15), in which the lid portion is arranged substantially parallel to the substrate.

(17) The semiconductor device according to any one of (1) to (16), in which the semiconductor chip is an imaging element.

(18) The semiconductor device according to (17), in which the lid portion contains a material that allows light in a band including visible light to pass through.

(19) A semiconductor device manufacturing method including: a step of applying resin along an outer peripheral portion of a surface of a substrate, the substrate including wiring and having a first pad electrically connected to the wiring on the surface; a step of forming a shape having, on an upper surface, a plurality of projection portions and a groove portion corresponding to each of the projection portions by pressing a molding frame against the resin, and curing the resin to form a wall portion having an annular shape; a step of bonding a semiconductor chip having a terminal to a surface of the substrate surrounded by the wall portion; a step of electrically connecting a terminal of the semiconductor chip and the first pad of the substrate; a step of applying an adhesive to a region excluding the projection portions and the groove portion on an upper surface of the wall portion; and a step of fixing a lid portion to an upper surface of the wall portion by placing the lid portion on the upper surface of the wall portion and applying pressure to the lid portion.

(20) The semiconductor device manufacturing method according to (19), further including a step of forming a second pad electrically connected to the wiring, on a lower surface of the substrate.

What is claimed is:

1. A semiconductor device, comprising:
a substrate;
a frame having a wall portion that is annularly arranged on the substrate and has a plurality of projection portions on an upper surface, the frame having a groove portion provided on the upper surface of the wall portion in correspondence to each of the projection portions;
a semiconductor chip arranged in a region surrounded by the wall portion on the substrate; and
a lid portion arranged on the upper surface of the wall portion and sealing the semiconductor chip.

2. The semiconductor device according to claim 1, wherein the semiconductor chip has at least one terminal, the substrate has at least one first pad and a wiring portion connected to the first pad, and the semiconductor device further includes a wire configured to electrically connect the terminal and the first pad.

3. The semiconductor device according to claim 2, further comprising a second pad arranged on a lower surface of the substrate and electrically connected to the wiring portion.

4. The semiconductor device according to claim 1, wherein the wall portion has a substantially rectangular shape in plan view from an upper surface side, and the plurality of projection portions is separately arranged on an inner peripheral side of two opposing sides of the wall portion.

5. The semiconductor device according to claim 1, wherein the groove portion is provided on an outer peripheral side of the wall portion with respect to each of the projection portions.

6. The semiconductor device according to claim 1, wherein the groove portion is annularly provided on the upper surface of the wall portion.

7. The semiconductor device according to claim 1, wherein the wall portion has a substantially rectangular shape in plan view from an upper surface side, and the plurality of projection portions is arranged on an outer peripheral side of four corner portions of the wall portion.

8. The semiconductor device according to claim 7, wherein the groove portion is arranged on an inner peripheral side of the wall portion with respect to each of the projection portions.

9. The semiconductor device according to claim 1, wherein an upper end portion of each of the projection portions has a rounded shape in a cross section cut in a vertical direction.

10. The semiconductor device according to claim 1, wherein an upper end portion of each of the projection portions has a trapezoidal shape in a cross section cut in a vertical direction.

11. The semiconductor device according to claim 1, wherein the wall portion has three or more of the projection portions.

12. The semiconductor device according to claim 11, wherein the three or more projection portions are arranged at apex positions of a polygon in plan view of the wall portion viewed from an upper surface side.

13. The semiconductor device according to claim 1, further comprising a bonding member arranged in a region where none of the projection portions are present in an upper surface portion of the wall portion, the bonding member bonding the frame and the lid portion.

14. The semiconductor device according to claim 13, wherein the bonding member is arranged in at least a part of an inside of the groove portion.

15. The semiconductor device according to claim 1, wherein heights from an upper surface of the substrate to upper end portions of the plurality of projection portions are substantially equal.

16. The semiconductor device according to claim 1, wherein the lid portion is arranged substantially parallel to the substrate.

17. The semiconductor device according to claim 1, wherein the semiconductor chip is an imaging element.

18. The semiconductor device according to claim 17, wherein the lid portion contains a material that allows light in a band including visible light to pass through.
